(19) United States
(12) Patent Application Publication
(10) Pub. No.: US 2017/0032836 A1
(43) Pub. Date: Feb. 2, 2017

(54) SEMICONDUCTOR DEVICE THAT PERFORMS TEMPERATURE-BASED DATA WRITING OPERATION

(71) Applicant: KABUSHIKI KAISHA TOSHIBA, Tokyo (JP)

(72) Inventors: Daisuke KIMURA, Yokohama Kanagawa (JP); Hayato MASUBUCHI, Ome Tokyo (JP)

(21) Appl. No.: 15/056,717

(22) Filed: Feb. 29, 2016

(30) Foreign Application Priority Data
Jul. 28, 2015 (JP) 2015-148429

(51) Int. Cl. G11C 11/56; G11C 16/14

(52) U.S. Cl. CPC G11C 11/5635; G11C 16/14

(57) ABSTRACT

A semiconductor device includes a substrate having a connector for connection with a host, a semiconductor memory device mounted on the substrate and including a plurality of memory cells, a temperature sensor mounted on the substrate, and a controller mounted on the substrate. The controller is configured to determine a number of bits per memory cell by which data are to be written in the semiconductor memory device, based on a temperature detected by the temperature sensor, and write the data in the semiconductor memory device by the determined number of bits per memory cell.

### CROSS-REFERENCE TO RELATED APPLICATION

This application is based upon and claims the benefit of priority from Japanese Patent Application No. 2015-148429, filed Jul. 28, 2015, the entire contents of which are incorporated herein by reference.

### FIELD

Embodiments described herein relate generally to a semiconductor device, in particular, a semiconductor device that performs temperature-based data writing operation.

### BACKGROUND

Generally, a semiconductor device including a non-volatile memory and a controller is known. For such a semiconductor device, data storage reliability is desired.

### DESCRIPTION OF THE DRAWINGS

FIG. 1 is a perspective view of a system including a semiconductor device according to an embodiment.

FIG. 2 is a perspective view of the semiconductor device, which is mounted on a host apparatus.

FIG. 3 is a cross-sectional view of a tablet that makes up the host apparatus.

FIGS. 4A to 4C illustrate the semiconductor device according to the embodiment, where FIG. 4A is a front view, FIG. 4B a rear view, and FIG. 4C a side view.

FIG. 5 is a block diagram of the semiconductor device according to the embodiment.

FIG. 6 is a cross-sectional view of a NAND memory and a controller in the semiconductor device.

FIG. 7 is a block diagram of the controller.

FIG. 8 is a flowchart that illustrates a write operation carried out by the controller.

FIG. 9 schematically illustrates a read operation performed by the controller.

FIG. 10 illustrates a threshold distribution when data are written in NAND memory.

### DETAILED DESCRIPTION

One or more embodiments described herein are directed to improving reliability of a semiconductor device and an electronic apparatus.

In general, according to an embodiment, a semiconductor device includes a substrate having a connector for connection with a host, a semiconductor memory device mounted on the substrate and including a plurality of memory cells, a temperature sensor mounted on the substrate, and a controller mounted on the substrate. The controller is configured to determine a number of bits per memory cell by which data are to be written in the semiconductor memory device, based on a temperature detected by the temperature sensor, and write the data in the semiconductor memory device by the determined number of bits per memory cell.

Hereinafter, one or more embodiments will be described with reference to the drawings.

In the present disclosure, a plurality of expressions may be used for several elements. However, these expressions are only an example, and the elements may be expressed by other expressions. Moreover, even if a plurality of expressions is not used for an element, the element may be expressed by another expression.

In addition, the drawings are schematic views, and the relationship between a thickness, a flat dimension or ratios of a thickness of each layer, or the like may be different from the actual one. Moreover, the relationship between dimensions, or ratios, or the like may be different between each drawing. Furthermore, some components or configurations may be omitted in some drawings for convenience of description.

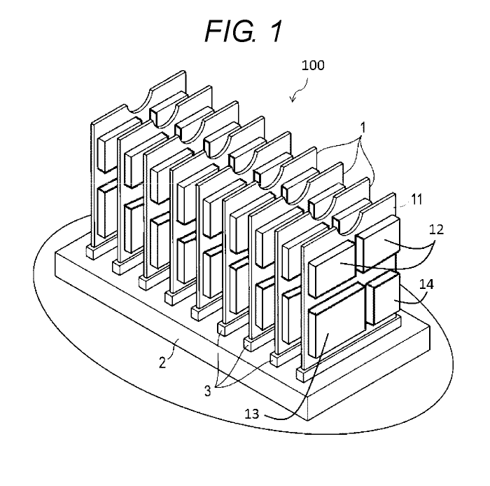

FIGS. 1 to 3 illustrate a semiconductor device 1 according to an embodiment and a system 100 including the semiconductor device 1. The system 100 is an example of an “electronic apparatus”. The semiconductor device 1 is an example of a “semiconductor module” and a “semiconductor memory apparatus”. The semiconductor device 1 according to the present embodiment is, for example, a memory system such as a solid state drive (SSD), but is not limited thereto.

As illustrated in FIG. 1, the semiconductor device 1 is included as a memory device in the system 100, which is, for example, a server or the like. The system 100 includes the semiconductor device 1 and a host apparatus 2 on which the semiconductor device 1 is mounted. The host apparatus 2 includes, for example, a plurality of connectors 3 (for example, a slot) that is open upward.

A plurality of the semiconductor devices 1 is respectively mounted on the connectors 3 of the host apparatus 2, and supported while standing in a substantially perpendicular direction. According to such configuration, it is possible to mount the plurality of semiconductor devices in a mass and in a compact manner, and to achieve miniaturization of the host apparatus 2.

In addition, the semiconductor device 1 may be used as a storage device of an electronic apparatus such as a notebook-type portable computer, a tablet terminal, or a detachable note personal computer (PC).

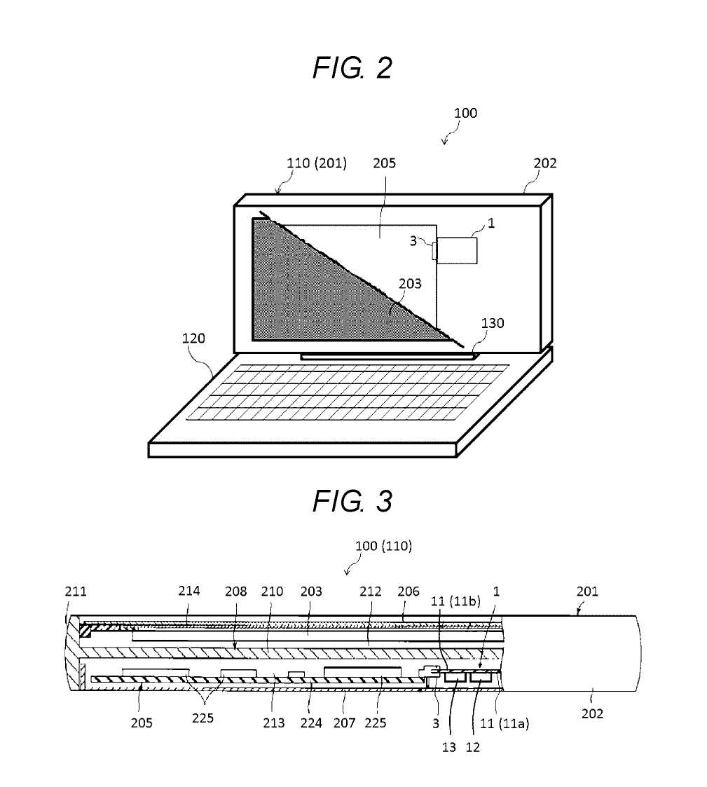

Hereinafter, with reference to FIGS. 2 and 3, an example will be described where the semiconductor device 1 is mounted on a detachable note PC, which corresponds to the host apparatus 2. Furthermore, since the detachable note PC is an example of the host apparatus 2, here, the detachable note PC will be attached with the same reference number, and will be described as a detachable note PC 2. In addition, here, the entire detachable note PC 2 to which the semiconductor device 1 is connected is referred to as the system 100. Hereinafter, it is assumed that the semiconductor device 1 is mounted on the detachable note PC 2, as an example.

FIG. 2 illustrates a detachable note PC including the semiconductor device 1 mounted thereon. FIG. 3 is a cross-sectional view of a displaying unit 110 (tablet-type portable computer 201) of the detachable note PC illustrated in FIG. 2. The detachable note PC is configured in such a manner that the displaying unit 110, and a keyboard unit 120, which is a first input reception device, are detachably connected to each other via a connecting unit 130. Furthermore, the portable computer 201 and the detachable note PC are respectively an example of the host apparatus 2.

As illustrated in FIGS. 2 and 3, the semiconductor device 1 is mounted on the displaying unit side of the detachable note PC. For this reason, even when detached, the displaying unit 110 can function as the tablet-type portable computer 201, which is a second input reception device.

The portable computer 201 is an example of an electronic apparatus, and, for example, has a size such that a user can use the computer by gripping in hand.

The portable computer 201 includes a housing 202, a display module 203, the semiconductor device 1, and a motherboard 205 as major elements. The housing 202 includes a protective plate 206, a base 207, and a frame 208. The protective plate 206 is a rectangular plate made of glass or plastic, and configures the surface of the housing 202. The base 207 is made of metal such as, aluminum alloy or magnesium alloy, and configures the bottom of the housing 202.

The frame 208 is provided between the protective plate 206 and the base 207. The frame 208 is made of metal such as, aluminum alloy or magnesium alloy, and includes a mounting portion 210 and a bumper portion 211, which are integrated with each other. The mounting portion 210 is provided between the mounting portion 210 and the protective plate 206 and the base 207. According to the present embodiment, the mounting portion 210 designates a first mounting space 212 between the mounting portion 210 and the protective plate 206, and a second mounting space 213 between the mounting portion 210 and the base 207.

The bumper portion 211 is integrally formed with the outer peripheral portion of the mounting portion 210, and continuously surrounds the first mounting space 212 and the second mounting space 213 in a circumferential direction. Moreover, the bumper portion 211 extends in the thickness direction of the housing 202 so as to be laid across the outer peripheral portion of the protective plate 206 and the outer peripheral portion of the base 207, and configures the outer peripheral surface of the housing 202.

The display module 203 is housed in the first mounting space 212 of the housing 202. The display module 203 is covered by the protective plate 206, and a touch panel 214 that has a handwriting function is disposed between the protective plate 206 and the display module 203. The touch panel 214 adheres to the rear surface of the protective plate 206.

As illustrated in FIG. 3, the semiconductor device 1 is housed in the second mounting space 213 of the housing 202 along with the motherboard 205. The semiconductor device 1 includes a substrate 11, a NAND memory 12, a controller 13, and an electronic component such as a DRAM 14.

The substrate 11 is, for example, a printed wiring board, and includes a first surface 11a on which a conductor pattern (not illustrated) is formed, and a second surface 11b positioned at the opposite side of the first surface 11a. A circuit component is mounted on the first surface 11a and the second surface 11b of the substrate 11, and soldered on the conductor pattern.

The NAND memory 12 includes a plurality of blocks, which includes a plurality of pages, and each page includes a plurality of memory cells. The page is a unit of data writing, and the block is a unit of data erasing, in one embodiment.

The motherboard 205 includes the substrate 224, and a plurality of circuit components 225, a semiconductor package, or a chip. On the substrate 224, a plurality of conductor patterns (not illustrated) is formed. The circuit component 225 is mounted on the substrate 224 and electrically connected while being soldered to the conductor pattern of the substrate 224.

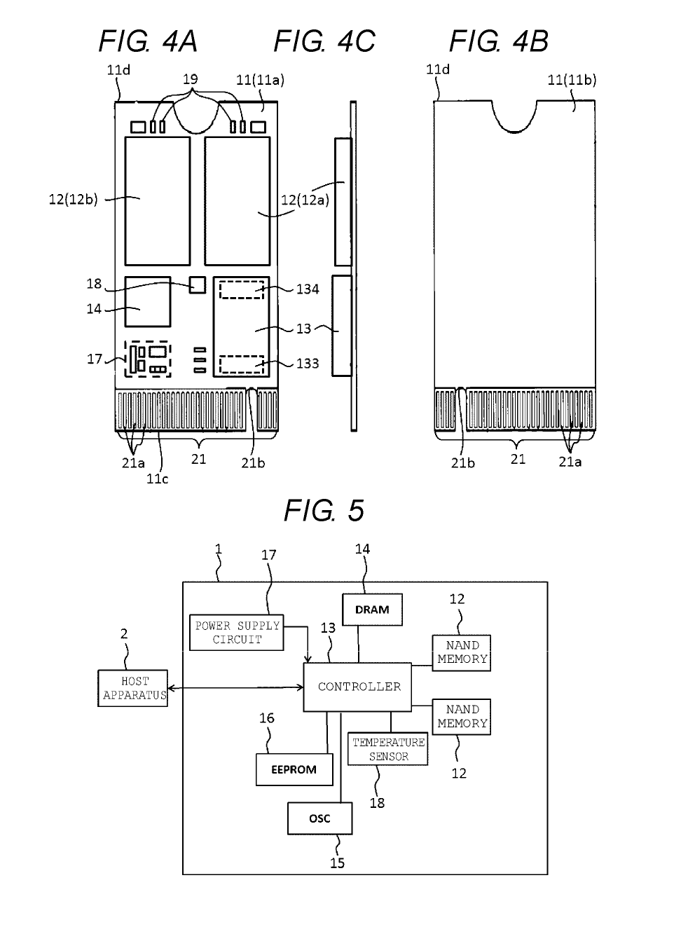

FIGS. 4A to 4C illustrate the exterior of the semiconductor device 1. FIG. 4A is a plan view, FIG. 4B is a bottom view, and FIG. 4C is a side view of the semiconductor device 1. In addition, FIG. 5 illustrates an example of a system configuration of the semiconductor device 1.

As illustrated in FIGS. 4A to 4C, the semiconductor device 1 includes the substrate 11, a NAND-type flash memory (hereinafter shortened as NAND memory) 12 as a non-volatile semiconductor memory, the controller 13, the dynamic random access memory (DRAM) 14 as a volatile semiconductor memory that is capable of operating at a speed faster than the NAND memory 12, an oscillator (OSC) 15, an electrically erasable and programmable ROM (EEPROM) 16, a power supply circuit 17, a temperature sensor 18, other electronic components 19 such as a resistor or a capacitor, and a pass-through connector 20.

Moreover, the NAND memory 12 and the controller 13 according to the present embodiment are mounted as a semiconductor package, which is an electronic component. For example, the semiconductor package of the NAND memory 12 is a System-in-Package (SiP) type module, in which a plurality of semiconductor chips is sealed inside one package. The controller 13 controls the operation of the NAND memory 12.

The substrate 11 is a circuit board in a substantially rectangular shape and formed of a material such as, for example, glass epoxy resin, and defines the exterior dimensions of the semiconductor device 1. The substrate 11 includes the first surface 11a, and the second surface 11b positioned at the opposite side to the first surface 11a. In addition, in the present disclosure, of surfaces of the substrate 11, the surfaces except for the first surface 11a and the second surface 11b are defined as “side surfaces” of the substrate 11.

In the semiconductor device 1, the first surface 11a is a component mounting surface, on which the NAND memory 12, the controller 13, the DRAM 14, the oscillator 15, the EEPROM 16, the power supply circuit 17, the temperature sensor 18, and other electronic components 19 such as a resistor or a capacitor, or the like are mounted.

Meanwhile, the second surface 11b of the substrate 11 according to the present embodiment is a non-component-mounting surface on which no component is mounted. In this manner, it is possible to gather protrusions of the components from the surface of the substrate 11 on only one side by positioning a plurality of components provided separately from the substrate 11 in a concentrated manner on one surface of the substrate 11. Thereby, it is possible to obtain a thinner semiconductor device 1 than in the case where a component protrudes from both the first surface 11a and the second surface 11b of the substrate 11.

As illustrated in FIGS. 4A to 4C, the substrate 11 includes a first edge 11c, and a second edge 11d positioned at the opposite side to the first edge 11c. The first edge 11c includes an interface unit 21 (a substrate interface unit, a terminal unit, and a connecting unit).

The interface unit 21 includes, for example, a plurality of connecting terminals 21a (metal terminal). The interface unit 21 is, for example, inserted to the connector 3 of the host apparatus 2, and electrically connected to the connector 3. The interface unit 21 exchanges a signal (a control signal and a data signal) with the host apparatus 2. Moreover, the host apparatus 2 here is, for example, the portable computer 201 described above.

The interface unit 21 related to the present embodiment is, for example, an interface conforming to the standard of PCIExpress (hereinafter, PCIe). That is, between the interface unit 21 and the host apparatus 2, a high-speed signal conforming to the standard of PCIe (high-speed differential signaling) is transmitted. In addition, the interface unit 21 may conform, for example, to other standards such as serial advanced technology attachment (SATA), universal serial bus (USB), serial attached SCSI (SAS), or the like. The semiconductor device 1 receives electrical power supplied from the host apparatus 2 through the interface unit 21.

Moreover, in the interface unit 21, a slit 21b is formed at a position shifted from the center along the transverse direction of the substrate 11, and a projection (not illustrated) or the like provided at the connector 3 side of the host apparatus 2 fits thereto. Thereby, it is possible to prevent the semiconductor device 1 from being attached with the front and rear surfaces reversed.

The power supply circuit 17 is, for example, a DC-DC converter, and generates predetermined voltage, which is necessary for the NAND memory 12 or the like, from the electrical power supplied from the host apparatus 2. Moreover, it is preferable that the power supply circuit 17 is provided in the vicinity of the interface unit 21 in order to suppress loss of the electrical power supplied from the host apparatus 2.

The controller 13 controls operation of the NAND memory 12. That is, the controller 13 controls the writing, the reading-out, and the erasing of data with regard to the NAND memory 12.

The DRAM 14 is an example of a volatile memory, and used for storing management information or data caching of the NAND memory 12. The oscillator 15 supplies an operation signal at a predetermined frequency to the controller 13. The EEPROM 16 stores a control program or the like as fixed information.

The temperature sensor 18 notifies the controller 13 of the temperature of the semiconductor device 1. Moreover, in the present embodiment, one temperature sensor 18 is mounted on the substrate 11, and the temperature of the semiconductor device 1 is monitored by the temperature sensor 18. Data corresponding to the temperature may be stored in a memory region of the NAND memory 12 (e.g., redundant region), which is different from a memory region in which user data (write data) are written.

In the present embodiment, on the substrate 11, various kinds of electronic components such as the NAND memory 12, the controller 13, the DRAM 14, or the like are mounted, and the respective temperature differs according to the operation state of the semiconductor device 1, the load applied on each electronic component, or the like. For this reason, the temperature of the semiconductor device 1 may not be strictly uniform.

In the present embodiment, the temperature of the semiconductor device 1″ is defined as the temperature measured at a position where the temperature sensor 18 is mounted. In other words, in the present embodiment, the temperature of the semiconductor device 1″ is the temperature at the vicinity of the mounting position of the temperature sensor 18.

In addition, the temperature sensor 18 may be mounted inside a package such as the NAND memory 12, the controller 13, or the like, and be provided on the surface of the package. In this case, the temperature sensor 18 can more accurately measure the temperature of the NAND memory 12 or the temperature of the controller 13.

Moreover, in the present embodiment, the number of the NAND memories, the mounting position of the NAND memory 12, or the like are not limited to that in the drawings. For example, in the present embodiment, the two NAND memories 12 (12a and 12b) are mounted on the first surface 11a of the substrate 11. However, the number of the NAND memories 12 is not limited thereto.

The pass-through connector 20 is a connector for connecting the semiconductor device 1 to other semiconductor device. The semiconductor device 1 can be connected to other semiconductor device through a harness (not illustrated) connected to the pass-through connector 20.

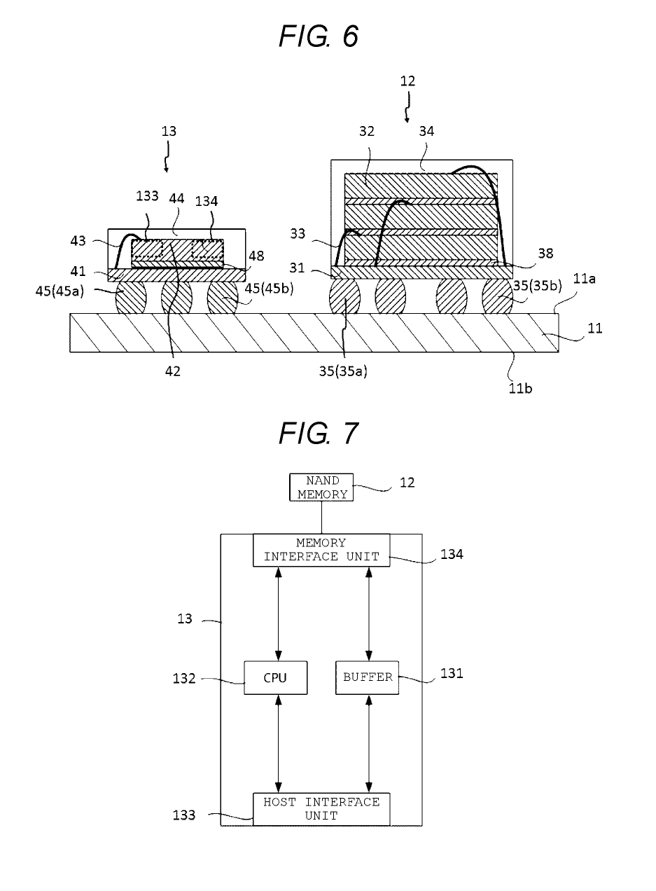

FIG. 6 illustrates a cross-sectional view of a semiconductor package as the NAND memory 12 and a semiconductor package as the controller 13 according to the present embodiment. The controller 13 includes a package substrate 41, a controller chip 42, a bonding wire 43, a sealing portion (molding material) 44, and a plurality of solder balls 45. The NAND memory 12 includes a package substrate 31, a plurality of memory chips 32, a bonding wire 33, a sealing portion (molding material) 34, and a plurality of solder balls 35.

The substrate 11 is, for example, a multi-layered circuit board as described above, includes a power supply layer, a ground layer, and internal wiring (, which are not illustrated), and electrically connects the controller chip 42 to the plurality of memory chips 32 through the bonding wires 33 and 43, the plurality of solder balls 35 and 45, or the like.

As illustrated in FIG. 6, on the package substrates 31 and 41, the plurality of solder balls 35 and 45 are provided. The plurality of solder balls 35 and 45 are, for example, arranged in a matrix shape on a second surface 31b of the package substrate 31. In addition, the plurality of solder balls 35 is not required to be arranged in full on the entire second surface 31b of the package substrate 31, and may be partially arranged.

In addition, the fixing of the package substrates 31 and 41 with the controller chip 42 and with the memory chip 32, and the fixing between the plurality of the memory chips 32 are performed by mount films 38 and 48.

Moreover, the memory chip 32 and the controller chip 42 may be mounted, after the mount films 38 and 48 are respectively stuck to the package substrates 31 and 41. In addition, for example, the mount film 48 may be stuck to a wafer used for the controller chip 42, and the wafer may be subjected to dicing to be divided into individual chips (controller chips 42). This also applies to the memory chip 32 and the mount film 38.

In addition, as illustrated in FIGS. 4A to 4C, the controller 13 in the present embodiment is in a substantially rectangular shape, and includes a first edge 13a in the transverse direction, a second edge 13b positioned at the opposite side to the first edge 13a, a third edge 13c in the longitudinal direction, and a fourth edge 13d positioned at the opposite side to the third edge 13c. Moreover, the second edge 13b is positioned at the NAND memory 12 side mounted on the substrate 11 being adjacent to the controller 13, and the first edge 13a is positioned at the interface unit 21 side included in the substrate 11.

Furthermore, the above-described solder balls 45 includes a solder ball 45a existing at the first edge 13a side, and a solder ball 45b existing at the second edge 13b side of the controller 13. In addition, the solder balls 35 includes a solder ball 35a positioned at the controller 13 side, and a solder ball 35b positioned at the opposite side to the solder ball 35a.

FIG. 7 illustrates an example of the system configuration of the controller 13. As illustrated in FIG. 7, the controller 13 includes a buffer 131, a central process unit (CPU) 132, a host interface unit 133, and a memory interface unit 134.

Moreover, as described above, the controller 13, for example, may have a function of the temperature sensor 18, or a function of the power supply circuit 17, and the system configuration of the controller 13 is not limited thereto.

The buffer 131 temporarily stores certain amount of data when writing data transmitted from the host apparatus 2 in the NAND memory 12, or temporarily stores certain amount of data when transmitting data read out from the NAND memory 12 to the host apparatus 2.

The CPU 132 controls the entire semiconductor device 1. The CPU 132 receives, for example, a command for writing data (write command), a command for reading out data (read command), and a command for erasing data from the host apparatus 2 (delete command) and accesses a corresponding region of the NAND memory 12, or controls a data transmitting process through the buffer 131.

The host interface unit 133 is positioned between the interface unit 21 of the substrate 11 and the CPU 132, and between the interface unit 21 and the buffer 131. The host interface unit 133 performs an interface process between the controller 13 and the host apparatus 2. Between the host interface unit 133 and the host apparatus 2, for example, a PCIe-high speed signal is transmitted.

Moreover, the host interface unit 133 is arranged, inside the controller 13, in the direction of the interface unit 21 of the substrate 11, that is, near the first edge 13a side. In this case, it is possible to shorten wiring between the host interface unit 133 and the interface unit 21 of the substrate 11.

For example, if the host interface unit 133 is arranged, inside the controller 13, apart from the interface unit 21, that is, near the second edge 13b (see FIGS. 4A to 4C), according to the length of the controller chip in the longitudinal direction, the length of the wiring connecting the interface unit 21 and the host interface unit 133 would increase. Owing to the increased wiring length, the parasitic capacitance, the parasitic resistance, the parasitic inductance, and the like would increase, and it would be difficult to maintain a characteristic impedance of a signal wiring. In addition, it also can be the cause of signal delay.

With respect to this point, it is preferable that the host interface unit 133 is arranged near the first edge 13a inside the controller 13. In this case, when a command is transmitted from the host apparatus 2, the interface unit 21 receives a signal from the host apparatus 2, and retrieves the signal with the host interface unit 133 from the wiring pattern of the substrate 11 through the solder ball 45a. Thereby, operation stability of the semiconductor device 1 can be improved.

In addition, it is preferable that, between the host interface unit 133 and the interface unit 21 of the substrate 11, the electronic component is not mounted.

As described above, when the length of the wiring between the host interface unit 133 and the interface unit 21 is long, problems may occur that it is difficult to maintain the impedance of the signal wiring, or it can be the cause of signal delay. Therefore, to make the wiring connecting the host interface unit 133 and the interface unit 21 be shortest as possible, that is, to make the connection be direct, it is not preferable that an electronic component is mounted between the host interface unit 133 and the interface unit 21.

In addition, the electronic components such as the power supply circuit 17 or the DRAM 14 may generate noise when operated. When such electronic components are not mounted between the host interface unit 133 and the interface unit 21, a signal exchanged between the host interface unit 133 and the interface unit 21 is less likely to include noise, and it is possible to improve operation stability of the semiconductor device 1.

The memory interface unit 134 is positioned between the NAND memory 12 and the CPU 132, and between the NAND memory 12 and the buffer 131. The memory interface unit 134 performs an interface process between the controller 13 and the NAND memory 12.

In the present embodiment, the memory interface unit 134 is arranged, inside the controller 13, apart from the interface unit 21 of the substrate 11, that is, near the second edge 13b. In this case, it is possible to shorten the length of the wiring between the memory interface unit 134 and the NAND memory 12.

A signal transmitted from the controller 13 is sent toward the wiring pattern of the substrate 11 through the solder ball 45b, and toward the memory chip 32 from the solder ball 35a. Thereby, the length of the wiring can be shortened, and operation stability of the semiconductor device 1 can be improved.

Moreover, between the memory interface unit 134 of the controller 13 and the NAND memory 12 of the substrate 11, it is preferable that the power supply circuit 17, the DRAM 14, or the like is not mounted. This is to lower the possibility that a signal exchanged between the memory interface unit 134 and the interface unit 21 includes noise, and to achieve improvement of the operation stability of the semiconductor device 1.

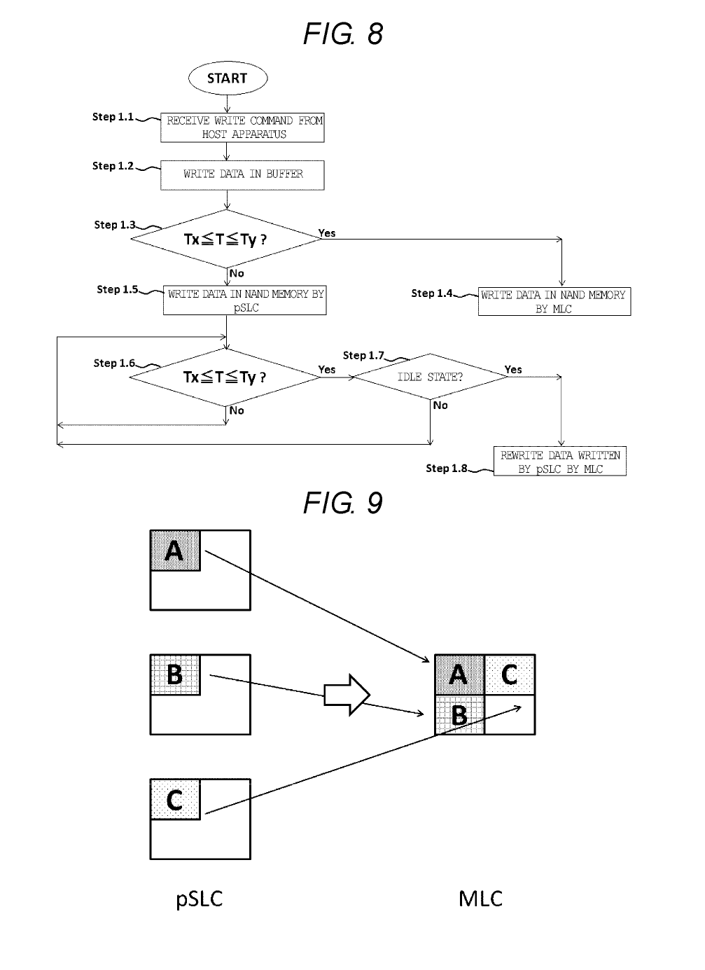

FIG. 8 is a flow chart that illustrates an operation of the controller 13 when data are written according to the present embodiment. Specifically, FIG. 8 illustrate a series of operations until data (data for writing) y are written in the NAND memory 12 according to a write command. The controller 13 receives commands such as a write command or a read command from the host apparatus 2.

Moreover, as described above, the semiconductor device 1 is, for example, a SSD. Generally, with regard to the SSD, as a method of writing data in memory such as the NAND memory 12, there are two types of writing methods of single level cell (SLC) and multi level cell (MLC).

According to the SLC, data of one bit including two values (0 or 1) are stored in each memory cell configuring the NAND memory 12. Meanwhile, according to the MLC, data of two bits or more including three or more values (for example, 00, 01, 10, 11, or the like) are stored in each memory cell configuring the NAND memory 12.

Hereinafter, it is assumed that the semiconductor device 1 according to the present embodiment is an SSD in which the MLC is applied as the method of writing data in the NAND memory 12.

First, the controller 13 receives a write command from the host apparatus 2 (Step 1.1). Here, the host apparatus 2 transmits address information or the like which includes, for example, amount of the data to be written or a writing position of the data, to the semiconductor device 1. The semiconductor device 1 receives this information, accesses the NAND memory 12, and determines whether it is possible to receive the data.

When it is possible to receive the data, that is, to write data according to the command, a response indicating that the writing is possible is returned to the host apparatus 2, and the data for writing is received from the host apparatus 2. In the flowchart in FIG. 8, this procedure is omitted, and it is assumed that the data writing in the NAND memory 12 is possible.

In addition, the host apparatus 2 and the semiconductor device 1 are not necessarily required to perform the exchange described above, and the host apparatus 2 may be configured to transmit data for writing to the semiconductor device 1 at the same time as when the write command is transmitted.

The controller 13 temporarily stores the data for writing received from the host apparatus 2 in the buffer 131 (Step 1.2). Here, the memory unit is, for example, a page.

After the writing of the data for writing in the buffer 131 is completed, the controller 13 receives the temperature information from the temperature sensor 18. In other words, the controller 13 checks temperature T of the semiconductor device 1 detected by the temperature sensor 18 (Step 1.3). In the present embodiment, the controller determines whether the temperature T of the semiconductor device 1 satisfies Tx≦T≦Ty. Here, Tx=10° C., and Ty=60° C. However, the temperature range is not limited thereto.

When T satisfies Tx≦T≦Ty, the controller 13 reads out the data for writing from the buffer 131, and writes the data for writing in the NAND memory 12. Here, in the NAND memory 12, the writing is performed by the MLC (Step 1.4).

Meanwhile, when T does not satisfy Tx≦T≦Ty, that satisfies, T is T<Tx, or Ty<T, the controller 13 reads out the data for writing from the buffer 131 and writes the data for writing in the NAND memory 12 by virtual SLC (Step 1.5).

As described above, the semiconductor device 1 writes the data in the NAND memory 12 by the MLC by default. Meanwhile, in Step 1.5, although it is possible to write the data by the MLC, data of one bit are written in each memory cell, instead. For this reason, in the present embodiment, this writing method is described as virtual SLC (hereinafter, pSLC).

Next, the controller 13 checks the peripheral temperature again (Step 1.6). The temperature is checked each predetermined time as described above.

When the temperature T of the semiconductor device 1 measured by the temperature sensor 18 satisfies Tx≦T≦Ty, the controller 13 confirms whether the semiconductor device 1 is in an Idle state (Step 1.7). In addition, here, the Idle state is, for example, a state where the semiconductor device 1 does not perform process such as the writing in the NAND memory 12 or the reading out from the NAND memory 12, and it is possible to perform Step 1.8.

When the semiconductor device 1 is not in the Idle state, the process returns to Step 1.6, and the temperature is checked again. Here, in the flowchart in FIG. 8, considering that the temperature of the semiconductor device 1 may change while determining whether the semiconductor device 1 is in the Idle state in Step 1.7, the process returns to Step 1.6 when the semiconductor device 1 is not in the Idle state. However, the return to Step 1.6 may not be required. For example, when the semiconductor device 1 is not in the Idle state, the controller 13 may wait until the semiconductor device 1 enters the Idle state.

When the semiconductor device 1 is in the Idle state, the data for writing by the pSLC are rewritten by the MLC (Step 1.8). FIG. 9 schematically illustrates a rewriting process of the data written into a block of the NAND memory 12.

In FIG. 9, as an example, in each page, data of A, B, and C are written by the pSLC. In Step 1.8, the data of A, B, and C written in each page are rewritten in pages of another block. When the rewriting is completed, the original data written by the pSLC are erased. As a result, it is possible to reuse the pages from which the data are erased as an empty area. When the data are erased in unit of block, the block in which the data are written may be different from a block in which the original data have been written.

Generally, in the semiconductor device 1, it is possible to write larger amount of data by performing the writing by the MLC. On the other hand, according to the MLC, the voltage of reading out (reading out level) of each data has to be more precise, and the fluctuation of the amount of the accumulated electric charge can easily be a problem. Therefore, the reliability of the data is better when writing by the SLC.

Meanwhile, unlike the writing by the SLC, the writing by the MLC may cause a shift of the threshold distribution due to the temperature of the semiconductor device 1.

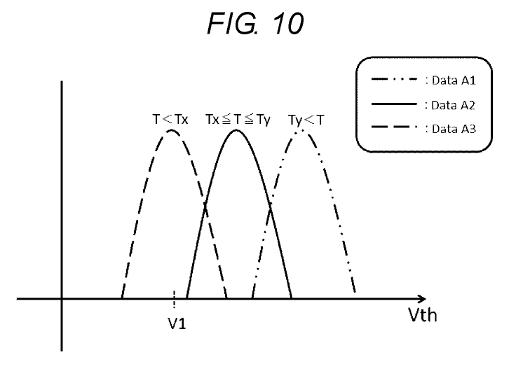

FIG. 10 illustrates a threshold distribution when data are written in the NAND memory 12 by the MLC. Data A1, Data A2, and Data A3 respectively indicate the threshold distribution when the temperature at which the writing is performed satisfies T<Tx, the threshold distribution when the temperature at which the writing is performed satisfies Tx≦T≦Ty, and the threshold distribution when the temperature at which the writing is performed satisfies Ty<T. Moreover, the content and size of the written data is the same among the Data A1, the Data A2, and the Data A3, and it is presumed that only the temperature at which the writing is performed is different.

In the NAND memory 12, the reading out is performed using voltage applied to the memory cell. Here, when the threshold distribution of the data to be read out is not in a predetermined voltage range (reading out level: V1), a reading-out error may occur. Moreover, the reading out level is set so as to read out the data written at normal temperature (in the present embodiment, Tx≦T≦Ty).

Meanwhile, the threshold distribution of the NAND memory 12 is, as illustrated in FIG. 10, shifted to the low voltage side (the threshold distribution is lowered) when the data are written at higher temperature, and shifted to the high voltage side (the threshold distribution is raised) when the data are written at lower temperature.

In FIG. 10, it is assumed that the Data A3 are read out (that is, the data to be read out are written at the high temperature, which satisfies Ty<T). In this case, it is possible to read out the Data A1 and the Data A2 with the reading out level at V1. Meanwhile, the threshold distribution of Data C, which are written at the temperature of Ty<T, is shifted further to low voltage side than the one of the Data A2 written at the temperature of Tx≦T≦Ty. For this reason, the threshold distribution crosses over the reading out level V1, and a reading out error may occur.

In the present embodiment, at the low temperature (T<Tx) and the high temperature (Ty<T), at which the threshold distribution can be easily changed, the data are written by the virtual SLC, according to which the threshold distribution is less likely to change, and the writing characteristic is better, and when the semiconductor device 1 is at the normal temperature, the data are rewritten by the MLC.

For this reason, the data written by the MLC are always written at the normal temperature (in the present embodiment, Tx≦T≦Ty), which are not likely to affect the writing characteristic, and it is possible to decrease the reading out error due to the shift of the threshold distribution.

Moreover, in the present embodiment, the data written once by the virtual SLC is rewritten by the MLC if the temperature of the semiconductor device 1 satisfies a predetermined condition (in the present embodiment, Tx≦T≦Ty).

For this reason, it is possible to more efficiently use the memory region of the NAND memory 12 while maintaining the reliability of the data.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a substrate having a connector for connection with a host;
a semiconductor memory device mounted on the substrate and including a plurality of memory cells;
a temperature sensor mounted on the substrate; and
a controller mounted on the substrate and configured to determine a number of bits per memory cell by which data are to be written in the semiconductor memory device, based on a temperature detected by the temperature sensor, and write the data in the semiconductor memory device by the determined number of bits per memory cell.

2. The semiconductor device according to claim 1, wherein
the controller writes the data by one bit per memory cell, when the temperature is outside a predetermined temperature range.

3. The semiconductor device according to claim 2, wherein
the controller writes the data by two or more bits per memory cell, when the temperature is within the predetermined temperature range.

4. The semiconductor device according to claim 2, wherein
the controller is further configured to rewrite the data that have been written by one bit per memory cell, in different memory cells of the semiconductor memory device by two or more bits per memory cell, when the temperature changes from being outside to within the predetermined temperature range.

5. The semiconductor device according to claim 4, wherein
the controller rewrites the data when no other access to the semiconductor memory device is performed.

6. The semiconductor device according to claim 4, wherein
after the rewriting of the data is carried out, the controller is further configured to erase the data that were written by one bit per memory cell.

7. The semiconductor device according to claim 1, wherein
the semiconductor memory device includes a first memory region in which the data are written and a second memory region for storing data corresponding to the temperature.

8. The semiconductor device according to claim 1, wherein each of the memory cells is a multi-level cell.

9. A computing device, comprising:
a display;
a mother board having a connector; and
a semiconductor memory module connected to the connector, and including
a substrate having a connector connected to the connector of the mother board,
a semiconductor memory device mounted on the substrate and including a plurality of memory cells,
a temperature sensor mounted on the substrate, and
a controller mounted on the substrate and configured to determine a number of bits per memory cell by which data are to be written in the semiconductor memory device, based on a temperature detected by the temperature sensor, and write the data in the semiconductor memory device by the determined number of bits per memory cell.

10. The computing device according to claim 9, wherein
the controller writes the data by one bit per memory cell, when the temperature is outside a predetermined temperature range.

11. The computing device according to claim 10, wherein
the controller writes the data by two or more bits per memory cell, when the temperature is within the predetermined temperature range.

12. The computing device according to claim 10, wherein
the controller is further configured to rewrite the data that have been written by one bit per memory cell, in different memory cells of the semiconductor memory device by two or more bits per memory cell, when the temperature changes from outside to within the predetermined temperature range.

13. The computing device according to claim 12, wherein
the controller rewrites the data when no other access to the semiconductor memory device is performed.

14. The computing device according to claim 12, wherein
after the rewriting of the data is carried out, the controller is further configured to erase the data that were written by one bit per memory cell.

15. The computing device according to claim 9, wherein
the semiconductor memory device includes a first memory region in which the data are written and a second memory region for storing data corresponding to the temperature.

16. The computing device according to claim 9, wherein each of the memory cells is a multi-level cell.

17. A method for writing data in a semiconductor memory device including a plurality of memory cells, the method comprising:
detecting temperature at a vicinity of the semiconductor memory device;
determining a number of bits per memory cell by which data are to be written in the semiconductor memory device, based on the detected temperature; and
writing the data in the semiconductor memory device by the determined number of bits per memory cell.

18. The method according to claim 17, wherein
the data are written by one bit per memory cell, when the detected temperature is outside a predetermined temperature range.

19. The method according to claim 18, wherein
the data are written by two or more bits per memory cell, when the detected temperature is within the predetermined temperature range.

20. The method according to claim 18, wherein
redetecting the temperature after the data have been written by one bit per memory cell; and
rewriting the data that have been written by one bit per memory cell, in different memory cells of the semiconductor memory device by two or more bits per memory cell, when the redetected temperature is within the predetermined temperature range.
